(19) United States
(12) Patent Application Publication
(10) Pub. No.: US 2025/0063842 A1
(43) Pub. Date: Feb. 20, 2025

(54) IMAGE SENSING DEVICE

(71) Applicant: SK hynix Inc., Icheon-si (KR)

(72) Inventor: Hyun Soo LIM, Icheon-si (KR)

(21) Appl. No.: 18/798,659

(22) Filed: Aug. 8, 2024

(30) Foreign Application Priority Data
Aug. 14, 2023 (KR) 10-2023-0106416

(51) Int. Cl. H01L 27/146

(52) U.S. Cl. CPC H01L 27/1463

(57) ABSTRACT

An image sensing device includes a plurality of unit pixels. A first unit pixel of the plurality of unit pixels includes first to fourth sub-pixels arranged in a 2×2 matrix, an isolation structure including first and second portions, the first portion formed to surround the first unit pixel, the second portion disposed between adjacent sub-pixels among the first sub-pixel to the fourth sub-pixel, a first junction region formed to surround a first transistor region and disposed across the first sub-pixel and the second sub-pixel along a first side of the first unit pixel, and a second junction region formed to surround a second transistor region and disposed across the third sub-pixel and the fourth sub-pixel along a second side parallel to the first side. The length of the first side is equal to the length of a third side of the first unit pixel perpendicular to the first side.

### CROSS-REFERENCE TO RELATED APPLICATION

This patent document claims the priority and benefits of Korean patent application No. 10-2023-0106416, filed on Aug. 14, 2023, the disclosure of which is incorporated by reference in its entirety as part of the disclosure of this patent document.

### TECHNICAL FIELD

The technology and implementations disclosed in this patent document generally relate to an image sensing device.

### BACKGROUND

An image sensing device is a semiconductor device for capturing and converting light of optical images into electrical signals for displaying the captured images and for further processing of the captured images. The recent development of various industries and sectors, including automotive, medical, computer and communication industries generates various demands for high-performance image sensing devices in various electronic devices such as smart phones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. CCD image sensing devices offer a better image quality, but they tend to consume more power and have a larger size as compared to the CMOS image sensing devices. CMOS image sensing devices are smaller in size and consume less power than the CCD image sensing devices. Furthermore, by using the CMOS fabrication technology, CMOS image sensing devices and signal processing circuitry can be integrated into a single chip, making it possible to miniaturize electronic devices while achieving reduction in production costs. Such characteristics make CMOS image sensing devices better suited for implementations in mobile devices.

### SUMMARY

Various embodiments of the disclosed technology relate to an image sensing device that includes a symmetrical pixel array, thereby electively performing a phase-difference detection autofocus (PDAF) function.

The disclosed technology can be implemented in some embodiments to provide an image sensing device capable of securing a sufficient transistor region while reducing its overall size.

In an embodiment of the disclosed technology, an image sensing device may include a plurality of unit pixels arranged in a row or column direction of a pixel array. A first unit pixel from among the plurality of unit pixels may include a first sub-pixel, a second sub-pixel, a third sub-pixel and a fourth sub-pixel arranged in a (2×2) matrix; a grid-shaped isolation structure formed to surround the first unit pixel and disposed between the first sub-pixel to the fourth sub-pixel; a first junction region formed to surround a first transistor region and disposed across the first sub-pixel and the second sub-pixel along a first side of the first unit pixel; and a second junction region formed to surround a second transistor region and disposed across the third sub-pixel and the fourth sub-pixel along a second side parallel to the first side, wherein a length of the first side is equal to a length of a third side of the first unit pixel perpendicular to the first side.

In an embodiment of the disclosed technology, an image sensing device may include a plurality of unit pixels configured to generate electrical signals based on incident light and arranged in a row direction or a column direction of a pixel array, wherein the plurality of unit pixels includes a first unit pixel, wherein the first unit pixel includes: a first sub-pixel, a second sub-pixel, a third sub-pixel and a fourth sub-pixel arranged in a 2×2 matrix; an isolation structure including a first portion and a second portion, the first portion formed to surround the first unit pixel, the second portion disposed between adjacent sub-pixels among the first sub-pixel to the fourth sub-pixel; a first junction region formed to surround a first transistor region and disposed across the first sub-pixel and the second sub-pixel along a first side of the first unit pixel; and a second junction region formed to surround a second transistor region and disposed across the third sub-pixel and the fourth sub-pixel along a second side parallel to the first side, wherein a length of the first side is equal to a length of a third side of the first unit pixel perpendicular to the first side.

In some implementations, the image sensing device may further include a first transistor region including a plurality of first transistors configured to process the electrical signals generated by the plurality of unit pixels, and a second transistor region including a plurality of second transistors configured to process the electrical signals generated by the plurality of unit pixels.

In some implementations, each of the first sub-pixel, the second sub-pixel, the third sub-pixel, and the fourth sub-pixel may include two photoelectric conversion elements that generate photocharge in response to incident light and disposed adjacent to each other.

In some implementations, the two photoelectric conversion elements may be arranged adjacent to each other in the row direction or the column direction of the pixel array.

In some implementations, each of the first to fourth sub-pixels may include transfer transistors that respectively overlap the two photoelectric conversion elements.

In some implementations, each of the photoelectric conversion elements may include a deep-doped region where impurities are doped to a first depth from a surface of the first unit pixel and a shallow-doped region where impurities are doped to a second depth from the surface of the first unit pixel, wherein the second depth is closer to the surface of the first unit pixel than the first depth.

In some implementations, the first unit pixel may include a first floating diffusion region disposed between the first sub-pixel and the third sub-pixel; and a second floating diffusion region disposed between the second sub-pixel and the fourth sub-pixel.

In some implementations, the first floating diffusion region and the second floating diffusion region may be arranged in a direction in which the first side extends.

In some implementations, the first transistor region may include a drive transistor and a selection transistor; and the second transistor region includes a gain conversion transistor and a reset transistor.

In some implementations, each of the first to fourth sub-pixels may be formed in a square shape.

In some implementations, the second unit pixel contacting the first unit pixel may include a third junction region formed to surround a third transistor region and disposed across a fifth sub-pixel and a sixth sub-pixel along a fifth side of the second unit pixel; and a fourth junction region formed to surround a fourth transistor region and disposed across a seventh sub-pixel and a eighth sub-pixel along a sixth side parallel to the fifth side, wherein the fifth side is in contact with a fourth side of the first unit pixel extending in a direction perpendicular to the first side.

In some implementations, a second unit pixel contacting the first unit pixel may include a fifth sub-pixel, a sixth sub-pixel, a seventh sub-pixel, and an eighth sub-pixel arranged in a (2×2) matrix. Each of the fifth sub-pixel, the sixth sub-pixel, the seventh sub-pixel, and the eighth sub-pixel may include two photoelectric conversion elements. The photoelectric conversion elements included in each of the fifth sub-pixel, the sixth sub-pixel, the seventh sub-pixel, and the eighth sub-pixel may be arranged to be adjacent to each other in a direction perpendicular to a direction in which photoelectric conversion elements included in each of the first sub-pixel, the second sub-pixel, the third sub-pixel, and the fourth sub-pixel are arranged.

In some implementations, the second unit pixel may further include a third floating diffusion region disposed between the fifth sub-pixel and the seventh sub-pixel; and a fourth floating diffusion region disposed between the sixth sub-pixel and the eighth sub-pixel, wherein the third floating diffusion region and the fourth floating diffusion region are arranged in a direction in which the photoelectric conversion elements included in each of the fifth sub-pixel, the sixth sub-pixel, the seventh sub-pixel, and the eighth sub-pixel are arranged.

In some implementations, the first transistor region may include a plurality of pixel transistors connected in parallel to each other.

In some implementations, the pixel transistors may include at least one of a drive transistor, a selection transistor, a reset transistor, and a gain conversion transistor.

In some implementations, the first unit pixel may further include a ground region disposed at a center of the first unit pixel and configured to receive a ground voltage as an input.

In some implementations, the second transistor region may include a capacitive element.

In some implementations, the isolation structure may be formed in a trench structure extending from one surface of a semiconductor substrate toward the other surface opposite to the one surface of the semiconductor substrate, and wherein the semiconductor substrate is which the photoelectric conversion elements are arranged.

In some implementations, the first junction region or the second junction region may be an impurity region extending from the other surface facing or opposite to one surface of the semiconductor substrate toward one surface of the semiconductor substrate.

In some implementations, the first junction region or the second junction region may be formed to at least partially overlap the isolation structure.

In some implementations, the width of the first junction region or the width of the second junction region is smaller than the width of the isolation structure surrounding the first unit pixel.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a first unit pixel included in a pixel array based on some implementations of the disclosed technology.

FIG. 3 is a cross-sectional view illustrating an example of the first unit pixel taken along a first cutting line based on some implementations of the disclosed technology.

FIG. 4 is a schematic diagram illustrating an example of a first metal layer connected to the first unit pixel based on some implementations of the disclosed technology.

FIG. 5 is a circuit diagram illustrating an example of the first unit pixel based on some implementations of the disclosed technology.

FIG. 6 is a layout diagram illustrating an example of first to fourth unit pixels based on some implementations of the disclosed technology.

### DETAILED DESCRIPTION

This patent document provides implementations and examples of an image sensing device that may be used in configurations to substantially address one or more technical or engineering issues and to mitigate limitations or disadvantages encountered in some other image sensing device designs. Some implementations of the disclosed technology relate to an image sensing device that includes a symmetrical pixel array to effectively perform a phase-difference detection autofocus (PDAF) function. Some implementations of the disclosed technology relate to an image sensing device capable of securing a sufficient transistor region while reducing an overall size of the image sensing device. The disclosed technology can be implemented in some embodiments to address the issues above by providing the image sensing device that can improve operation characteristics when performing a phase-difference detection autofocus (PDAF) function. The disclosed technology can be implemented in some embodiments to provide the image sensing device that includes unit pixels, each of which has a row-directional length and a column-directional length identical to each other, resulting in an increased degree of freedom in arranging such unit pixels. The disclosed technology can be implemented in some embodiments to provide the image sensing device that can secure symmetry between (1) a pixel signal output from unit pixels including photoelectric conversion elements adjacent to each other in the row direction of the pixel array and (2) another pixel signal output from unit pixels including photoelectric conversion elements adjacent to each other in the column direction of the pixel array. In some implementations, the photoelectric conversion elements may be configured to detect incident light and generate photocharge corresponding to the incident light.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

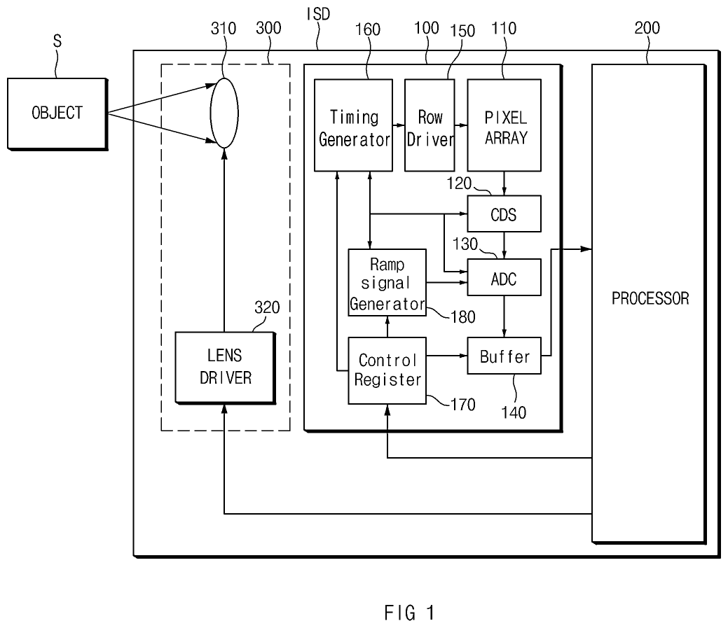

FIG. 1 is a block diagram illustrating an example of an image sensing device ISD based on some implementations of the disclosed technology.

As will be discussed below with reference to an example illustrated in FIG. 1, the image sensing device ISD can perform an autofocus (AF) function and may generate phase-difference data.

Referring to FIG. 1, the image sensing device ISD in the illustrated example may include an imaging circuit 300, an image sensor 100, and a processor 200.

The imaging circuit 300 may be a component that receives light. In some implementations, the imaging circuit 300 may include a lens 310 and a lens driver 320.

In one example, the lens 310 may be a single lens. In another example, the lens 310 may include a plurality of lenses.

The lens driver 320 may control the position of the lens 310 according to a control signal of a processor 200. As the position of the lens 310 is adjusted, the distance between the lens 310 and the target object(S) may also be adjusted.

The processor 200 may transmit a signal for adjusting the position of the lens 310 to the lens driver 320 based on a signal generated by the image sensor 100.

The image sensor 100 may include a pixel array 110, a correlated double sampler (CDS) 120, an analog-to-digital converter (ADC) 130, a buffer 140, a row driver 150, a timing generator 160, a control register 170, and a ramp signal generator 180.

In some implementations, the pixel array 110 may include at least one unit pixel. In an embodiment, each unit pixel may include sub-pixels and a transistor region.

At least one pair of photoelectric conversion elements included in a unit pixel may be arranged adjacent to each other in a row or column direction of the pixel array. The photoelectric conversion element may generate photocharge corresponding to incident light.

In some implementations, a phase-difference detection autofocus (PDAF) function can be performed using signals generated by a pair of photoelectric conversion elements included in one unit pixel and adjacent to each other.

The transistor region may include a plurality of transistors that generate an image signal or a phase difference signal based on photocharge generated in the photoelectric conversion element.

The photoelectric conversion element may provide an electrical signal (e.g., an image signal) corresponding to the generated charges to the correlated double sampler (CDS) 120.

Light (e.g., optical signal) that has passed through the lens 310 and is incident on the pixel array 110 may be converted into an electrical signal. Unit pixels may respectively generate electrical signals corresponding to a target object(S).

The correlated double sampler (CDS) 120 may sample and hold electrical signals received from the pixel array 110. The correlated double sampler (CDS) 120 may perform a double sampling operation on a signal level generated based on incident light and a specific noise level, and may thus output a signal level corresponding to a difference between the sampling resultant signals.

The analog-to-digital converter (ADC) 130 may convert the received analog signal into a digital signal, and may transmit the digital signal to the buffer 140.

The buffer 140 may hold or latch the received digital signals, and may sequentially output the latched digital signals to the processor 200. The buffer 140 may include a memory for holding the digital signal and a sense amplifier for amplifying the digital signal.

The row driver 150 may drive the plurality of unit pixels included in the pixel array 110 in response to an output signal of the timing generator 160.

For example, the row driver 150 may generate a selection signal to select any one of the row lines. In addition, the row driver 150 may generate signals (e.g., a transfer-transistor drive signal, a reset-transistor drive signal, a selection-transistor drive signal, etc.) to drive transistors contained in the unit pixels.

The timing generator 160 may control the row driver 150, such that the pixel array 110 can accumulate electric charges that are accumulated in response to incident light and temporarily store the accumulated electric charges or output an electrical signal corresponding to the electric charges to the outside of the pixel array 110.

The timing generator 160 may control the correlated double sampler (CDS) 120 to sample and hold electrical signals received from the pixel array 110.

The control register 170 may generate control signals to control the buffer 140, the timing generator 160, and the ramp signal generator 180 based on the signal received from the processor 200.

The ramp signal generator 180 may generate a reference signal that enables the analog-to-digital converter (ADC) 130 to detect a signal in response to a control signal received from the timing generator 160.

The processor 200 may receive an output signal of the buffer 140 as an input, such that the processor 200 can generate image data or phase difference data based on the received signal. In addition, the processor 200 may transmit a control signal for the lens driver 320 using the phase difference data.

The processor 200 may generate phase difference data for the target object(S) using signals respectively corresponding to a plurality of photoelectric conversion elements included in an arbitrary unit pixel.

The processor 200 may generate phase data for the target object(S) by calculating signals generated by a plurality of photoelectric conversion elements included in one unit pixel.

If the distance between the lens 310 and the target object(S) is considered to be at “in-focus position,” incident light beams that have reached the photoelectric conversion elements included in the unit pixel may have the same magnitude. Thus, the signals detected by the photoelectric conversion elements included in one unit pixel may have the same magnitude. Therefore, when the distance between the lens 310 and the target object(S) satisfies the in-focus position, phase data generated by the processor 200 may be identical.

On the other hand, when the distance between the lens 310 and the target object(S) does not satisfy the in-focus position, a difference between paths of the incident light may occur in a horizontal or vertical direction, so that incident light beams arriving at the photoelectric conversion elements may have different intensities (e.g., magnitudes) from each other. That is, the intensities of light that reaches the respective photoelectric conversion elements are different because paths for the incident light beams arriving at the photoelectric conversion elements are different in a horizontal or vertical direction. As a result, signals respectively detected by the photoelectric conversion elements included in one unit pixel may have different intensities.

If the distance between the lens 310 and the target object(S) does not satisfy the in-focus position, the processor 200 may calculate a phase difference between the phase data and the other phase data, and may thus generate phase difference data.

The processor 200 may provide a control signal for the lens driver 320 based on the phase difference data, and may perform the autofocus function by adjusting the distance between the target object(S) and the lens 310 and the distance between the pixel array 110 and the lens 310 using the control signal.

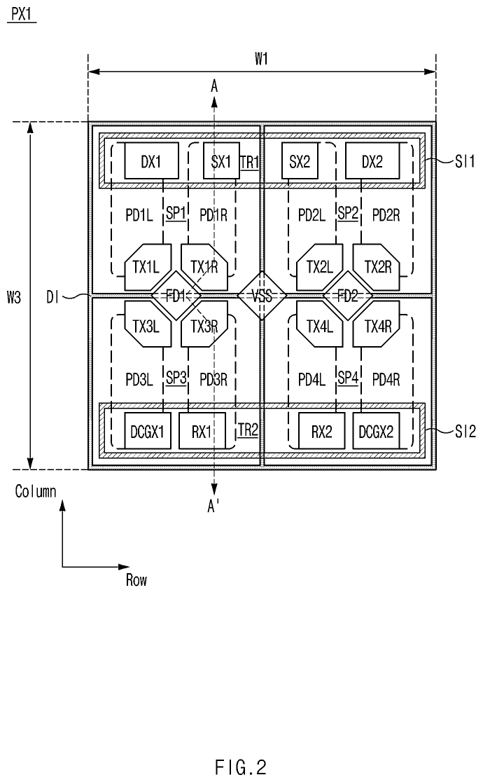

FIG. 2 is a plan view illustrating an example of a first unit pixel (PX1) included in the pixel array 110 of FIG. 1 based on some implementations of the disclosed technology.

Referring to FIG. 2, the pixel array 110 may include a plurality of unit pixels. Here, one unit pixel (e.g., PX1) may be a minimum unit of a layout structure repeatedly arranged within the pixel array 110.

The pixel array may include an isolation structure (DI) that is disposed between the first unit pixel PX1 and another unit pixel adjacent to the first unit pixel PX1 and is also disposed between sub-pixels (SP1-SP4) included in the first unit pixel PX1. For example, the isolation structure (DI) may include a first portion that is disposed between adjacent unit pixels (e.g., PX1 and another unit pixel adjacent to PX1) and a second portion that is disposed between adjacent sub-pixels (e.g., between SP1 and SP2, between SP2 and SP4, between SP4 and SP3, and between SP3 and SP1).

For example, the isolation structure (DI) may include the first portion that has a grid shape within the pixel array and surrounds each unit pixel in the pixel array (e.g., the first unit pixel PX1). In addition, the isolation structure (DI) may include the second portion that is disposed between the plurality of sub-pixels (SP1-SP4).

One sub-pixel (e.g., SP1) may be located in each grid region defined by the isolation structure (DI) including horizontal line portions and vertical line portions. In some implementations, the grid region defined by the isolation structure (DI) may be formed in a square shape in which the length in a row-directional of the pixel array is identical to the length in a column-directional of the pixel array.

The isolation structure (DI) may be a trench structure extending from one surface of a semiconductor substrate on which the pixel array is arranged toward the other surface of the semiconductor substrate. In some implementations, the isolation structure (DI) may include an insulation material such as silicon oxide.

The first unit pixel PX1 may include first to fourth sub-pixels (SP1-SP4). Each sub-pixel (e.g., SP1) may include two photoelectric conversion elements (e.g., PD1L, PD1R) and transfer transistors (e.g., TX1L, TX1R) formed to overlap the photoelectric conversion elements (e.g., PD1L, PD1R).

Each of the first to fourth sub-pixels (SP1-SP4) included in the first unit pixel PX1 may include photoelectric conversion elements (e.g., PD1L, PD1R) arranged in the row direction of the pixel array.

The photoelectric conversion elements (e.g., PD1L, PD1R) and the transfer transistors (e.g., TX1L, TX1R) included in each of the first to fourth sub-pixels (SP1-SP4) may be arranged symmetrical with respect to the row direction of the pixel array.

The image sensing device may generate phase difference data by comparing (1) pixel signals corresponding to photoelectric conversion elements (PD1L, PD2L, PD3L, PD4L) located on the left side with respect to the row direction of the pixel array with (2) pixel signals corresponding to photoelectric conversion elements (PD1R, PD2R, PD3R, PD4R) located on the right side with respect to the row direction of the pixel array.

The first unit pixel PX1 may include a first transistor region TR1 located along a first side of the first unit pixel PX1 and a second transistor region TR2 located along a second side parallel to the first side.

The first transistor region TR1 may include transistors different from the second transistor region TR2.

For example, the first transistor region TR1 may include drive transistors (DX1, DX2) and selection transistors (SX1, SX2), and the second transistor region TR2 may include gain conversion transistors (DCGX1, DCGX2) and reset transistors (RX1, RX2).

The transistors included in the first transistor region TR1 may be arranged symmetrical to each other with respect to the center of the first transistor region TR1. In addition, the transistors included in the second transistor region TR2 may be arranged symmetrical to each other with respect to the center of the second transistor region TR2.

The drive transistors (DX1, DX2) disposed in the first transistor region TR1 may be connected in parallel to each other through a metal layer, and may operate as one drive transistor.

Since the combination of the two drive transistors (DX1, DX2) operates as a single drive transistor, each drive transistor can have a larger gate area and can reduce noises.

In addition, the selection transistors (SX1, SX2) may be connected to each other through a metal layer, so that the selection transistors (SX1, SX2) can operate as a single selection transistor.

Gain conversion transistors (DCGX1, DCGX2) and reset transistors (RX1, RX2) disposed in the second transistor region TR2 may respectively be connected to each other to operate as a single transistor, and parasitic capacitance of each transistor can be adjusted according to the connection relationship between such transistors.

In some implementations, the layout structure can be configured such that the unit pixel PX1 may include an additional capacitive element by arranging dummy transistor(s) instead of the second gain conversion transistor DCGX2 and the second reset transistor RX2.

The first transistor region TR1 may be disposed across the first sub-pixel SP1 and the second sub-pixel SP2, and the second transistor region TR2 may be disposed across the third sub-pixel SP3 and the fourth sub-pixel SP4.

The first unit pixel PX1 may include a first junction region SI1 surrounding the first transistor region TR1 and a second junction region SI2 surrounding the second transistor region TR2.

The first junction region SI1 and the second junction region SI2 may be impurity regions extending from the other surface of the semiconductor substrate including the photoelectric conversion elements (e.g., PD1L, PD1R) toward one surface opposite to the other surface of the semiconductor substrate.

In other words, the junction regions (e.g., SI1, SI2) and the isolation structure (DI) may be arranged to be in contact with different surfaces of the semiconductor substrate.

In some implementations, at least a portion of the junction regions (e.g., SI1 and SI2) may be arranged to overlap the isolation structure (DI).

The width of the junction region (e.g., SI1, SI2) may be smaller than the width of the isolation structure (DI) surrounding the unit pixel (e.g., PX1). The width of the junction regions (SI1, SI2) may refer to a longer side of the area occupied by the junction regions (SI1, SI2) in the row direction or the column direction of the pixel array.

For example, as shown in FIG. 2, the width of the first junction region SI1 or the width of the second junction region SI2 may refer to the length in the row direction of the pixel array. The length of the first junction region SI1 or the length of the second junction region SI2 in the row direction of the pixel array may be shorter than the length of the isolation structure (DI) in the row direction of the pixel array.

As the width of the junction region (e.g., SI1, SI2) is formed to be smaller than the width of the isolation structure (DI) surrounding the unit pixel (e.g., PX1), the junction region (e.g., SI1, SI2) may be disposed in the unit pixel (e.g., PX1).

The junction region (e.g., SI1) may be disposed across adjacent sub-pixels (e.g., SP1, SP2).

In addition, the first unit pixel PX1 may include a plurality of floating diffusion regions (FD1, FD2) and a ground region (VSS) that overlap the isolation structure (DI).

The floating diffusion regions (FD1, FD2) and the ground region (VSS) may be impurity-doped regions in contact with the other surface of the semiconductor substrate in the same manner as the first junction region SI1 and the second junction region SI2.

The floating diffusion regions (FD1, FD2) and the ground region (VSS) may be arranged in a direction (e.g., the row direction of the pixel array) in which the first side of the first unit pixel PX1 extends.

The first floating diffusion region FD1 included in the first unit pixel PX1 may be electrically connected to the transfer transistors (TX1L, TX1R) included in the first sub-pixel SP1 and the transfer transistors (TX3L, TX3R) included in the third sub-pixel SP3. Accordingly, the first floating diffusion region FD1 may receive photocharge from the photoelectric conversion elements (PD1L, PD1R) included in the first sub-pixel SP1 and the photoelectric conversion elements (PD3L, PD3R) included in the third sub-pixel SP3.

The second floating diffusion region FD2 included in the first unit pixel PX1 may be electrically connected to the transfer transistors (TX2L, TX2R) included in the second sub-pixel SP2 and the transfer transistors (TX4L, TX4R) included in the fourth sub-pixel SP4. Accordingly, the second floating diffusion region FD2 may receive photocharge from the photoelectric conversion elements (PD2L, PD2R) included in the second sub-pixel SP2 and the photoelectric conversion elements (PD4L, PD4R) included in the fourth sub-pixel SP4.

The first unit pixel PX1 may have a square layout with four sides of the same length. For example, the length W1 of the first side of the first unit pixel PX1 may be equal to the length W3 of the third side of the first unit pixel PX1.

For example, the first side may be a side extending in the row direction of the pixel array, and the third side may be a side extending in the column direction of the pixel array. The first unit pixel PX1 may include sides having the same length in the row and column directions of the pixel array.

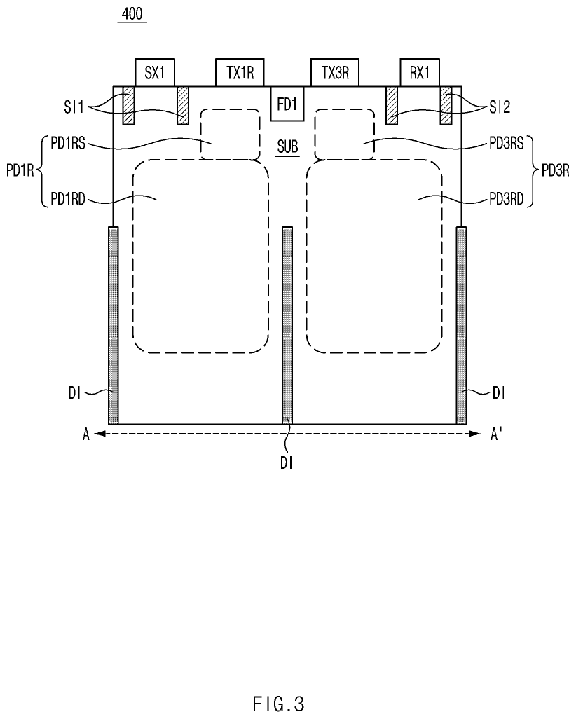

FIG. 3 is a cross-sectional view 400 illustrating an example of the first unit pixel PX1 taken along a first cutting line A-A′ based on some implementations of the disclosed technology.

Specifically, the vertical positions of a plurality of elements included in the first unit pixel PX1 are shown in FIG. 3.

Referring to the cross-sectional view 400 of FIG. 3, the image sensing device may include a plurality of photoelectric conversion elements (PD1R, PD3R) arranged in a semiconductor substrate SUB.

The semiconductor substrate SUB may include one surface and the other surface facing or opposite to the one surface. For example, the semiconductor substrate SUB may be a monocrystalline silicon substrate. In some implementations, the semiconductor substrate SUB may be a P-type or N-type bulk substrate. In some implementations, the semiconductor substrate SUB may be a substrate formed by growing a P-type or N-type epitaxial layer on the P-type bulk substrate. In some implementations, the semiconductor substrate SUB may be a substrate formed by growing a P-type or N-type epitaxial layer on the N-type bulk substrate. For convenience of description, it is assumed that the semiconductor substrate SUB is a substrate formed by growing a P-type epitaxial layer on the P-type bulk substrate. Each of the photoelectric conversion elements (PD1R, PD3R) may be implemented as a photodiode, a phototransistor, a photogate, a pinned photodiode (PPD), or a combination thereof. For convenience of description, it is assumed that each of the photoelectric conversion elements (PD1R, PD3R) is a photodiode as an example.

The photoelectric conversion elements (PD1R, PD3R) may be formed as N-type doped regions in the semiconductor substrate SUB through an ion implantation process that implants N-type ions. The photoelectric conversion elements (PD1R, PD3R) may include a structure in which a plurality of doped regions is stacked in a vertical direction.

The photoelectric conversion elements (PD1R, PD3R) may be arranged across as large a region as possible to increase light reception (Rx) efficiency of the unit pixel. The photoelectric conversion elements (PD1R, PD3R) may individually output signals corresponding to incident light.

In some implementations, each of the plurality of photoelectric conversion elements may include deep-doped regions (PD1RD, PD3RD) and shallow-doped regions (PD1RS, PD3RS). The deep-doped regions (PD1RD, PD3RD) and shallow-doped regions (PD1RS, PD3RS) may have a vertically stacked structure. In some implementations, the photoelectric conversion element PD1R may include the deep-doped region PD1RD and the shallow-doped region PD1RS that are vertically stacked, and the photoelectric conversion element PD3R may include the deep-doped region PD3RD and the shallow-doped region PD3RS that are vertically stacked. In some implementations, the term “shallow-doped region” may be used to indicate a doped region where impurities are doped to a certain depth that is close to the surface of the region, and the term “deep-doped region” may be used to indicate a doped region where impurities are doped to a depth that is deeper than the depth of the impurities of the shallow-doped region.

The shallow-doped regions (PD1RS, PD3RS) may be disposed adjacent to the first floating diffusion region FD1 so that photocharge generated by the deep-doped regions (PD1RD, PD3RD) can be easily transferred to the first floating diffusion region FD1.

The first floating diffusion region FD1 may be a region formed through an ion implantation process that implants N-type ions into the semiconductor substrate SUB, and may be a region for receiving photocharge generated by the photoelectric conversion elements (PD1R, PD3R).

Photocharge generated by the photoelectric conversion elements (PD1R, PD3R) may be transferred to the first floating diffusion region FD1 by the transfer transistors (TX1R, TX3R).

The transfer transistors TX1R and TX3R may be arranged to overlap the photoelectric conversion elements PD1R and PD3R, respectively. In some implementations, the transfer transistor TX1R may be arranged to overlap the photoelectric conversion element PD1R, and the transfer transistors TX3R may be arranged to overlap the photoelectric conversion element PD3R.

Each of the transfer transistors TX1R and TX3R may include a gate formed to receive a transfer signal, and a gate insulation layer formed to electrically isolate the gate and the semiconductor substrate SUB from each other. The gate may include a conductive material such as polysilicon or metal, and the gate insulation layer may include an insulation material such as silicon oxide.

Photocharge generated by the photoelectric conversion elements (PD1R, PD3R) may be transferred to the first floating diffusion region FD1 according to the transfer signals applied to the transfer transistors (TX1R, TX3R). In some implementations, photocharge generated by the photoelectric conversion element PD1R may be transferred to the first floating diffusion region FD1 according to the transfer signal applied to the transfer transistors TX1R, and photocharge generated by the photoelectric conversion element PD3R may be transferred to the first floating diffusion region FD1 according to the transfer signal applied to the transfer transistors TX3R.

The first selection transistor SX1 may be disposed in a region (e.g., a first transistor region) defined by the first junction region SI1, and the first reset transistor RX1 may be disposed in a region (e.g., a second transistor region) defined by the second junction region SI2.

The first junction region SI1 and the second junction region SI2 may extend from the other surface of the semiconductor substrate SUB toward one surface of the semiconductor substrate SUB. The first junction region SI1 may be formed to electrically isolate elements (e.g., SX1) located in the first transistor region from other elements (e.g., FD1), and the second junction region SI2 may be formed to electrically isolate elements (e.g., RX1) located in the second transistor region from other elements (e.g., FD1).

In some implementations, the first junction region SI1 and the second junction region SI2 may be regions doped with P-type impurities on the semiconductor substrate SUB. Since the first junction region SI1 and the second junction region SI2 are formed, the influence of leakage current occurring in the transistor region may be reduced.

The first selection transistor SX1 may include a gate formed to receive a selection signal and a gate insulation layer formed to electrically isolate the gate and the semiconductor substrate SUB from each other. In addition, the first reset transistor RX1 may include a gate formed to receive a reset signal, and a gate insulation layer formed to electrically isolate the gate and the semiconductor substrate SUB from each other.

The gate may include a conductive material such as polysilicon or metal, and the gate insulation layer may include an insulation material such as silicon oxide.

The isolation structure (DI) may be disposed between adjacent photoelectric conversion elements (PD1R, PD3R).

The isolation structure (DI) may have a trench structure that extends from one surface of the semiconductor substrate SUB toward the other surface of the semiconductor substrate SUB. The isolation structure (DI) may optically and electrically isolate (or separate) adjacent photoelectric conversion elements from each other.

The isolation structure (DI) may extend in a direction perpendicular to one surface of the semiconductor substrate SUB, and may include an insulation material such as silicon oxide or silicon nitride.

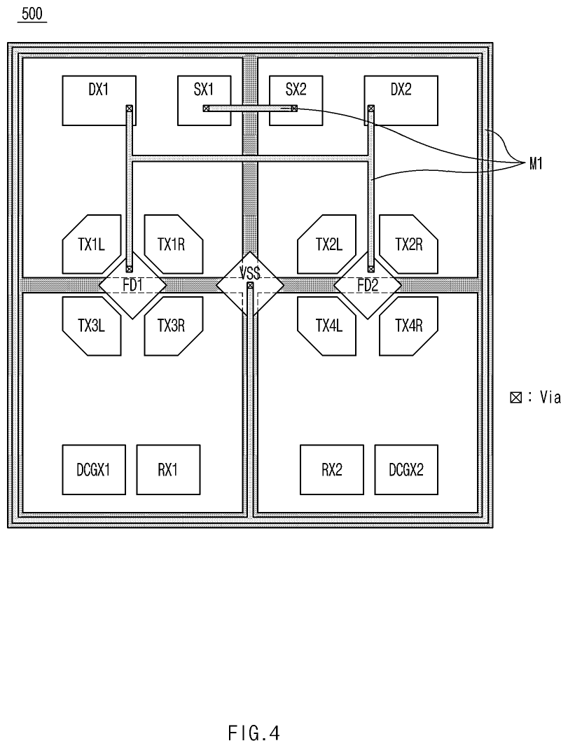

FIG. 4 is a schematic diagram illustrating an example of a first metal layer M1 connected to the first unit pixel PX1 based on some implementations of the disclosed technology.

Referring to FIG. 4, the metal layer M1 and the transistor (e.g., DX1, SX1, etc.) may be connected by a vertical via.

FIG. 4 shows an example of a portion of the first metal layer M1, and the layout structure of FIG. 4 may be different from the metal layer provided in an actual semiconductor device.

In FIG. 4, a metal layer connected to the transfer transistors (TX1L, TX1R, TX2L, TX2R, TX3L, TX3R, TX4L, TX4R) and a metal layer connected to the reset transistors (RX1, RX2) and the gain conversion transistors (DCGX1, DCGX2) are omitted for convenience of description.

In another example, a metal layer connected to the transfer transistors (TX1L, TX1R, TX2L, TX2R, TX3L, TX3R, TX4L, TX4R) or a metal layer connected to the reset transistors (RX1, RX2) and the gain conversion transistors (DCGX1, DCGX2) may be included in a metal layer provided in another layer.

Referring to FIG. 4, the first floating diffusion region FD1 and the second floating diffusion region FD2 may be electrically connected to each other by the first metal layer M1.

The first floating diffusion region FD1 and the second floating diffusion region FD2 connected to each other may be connected to the drive transistors (DX1, DX2) through the first metal layer M1. The first drive transistor DX1 and the second drive transistor DX2 may operate as one drive transistor.

The first metal layer M1 may connect the selection transistors (SX1, SX2) to each other, and the combination of the selection transistors (SX1, SX2) may operate as a single selection transistor.

The first metal layer M1 may overlap the isolation structure (DI), and may be connected to the ground region VSS. The first metal layer M1 may be arranged to surround the first unit pixel (PX1), and the ground voltage may be applied to the ground region VSS, reducing the parasitic capacitance caused by the first metal layer M1.

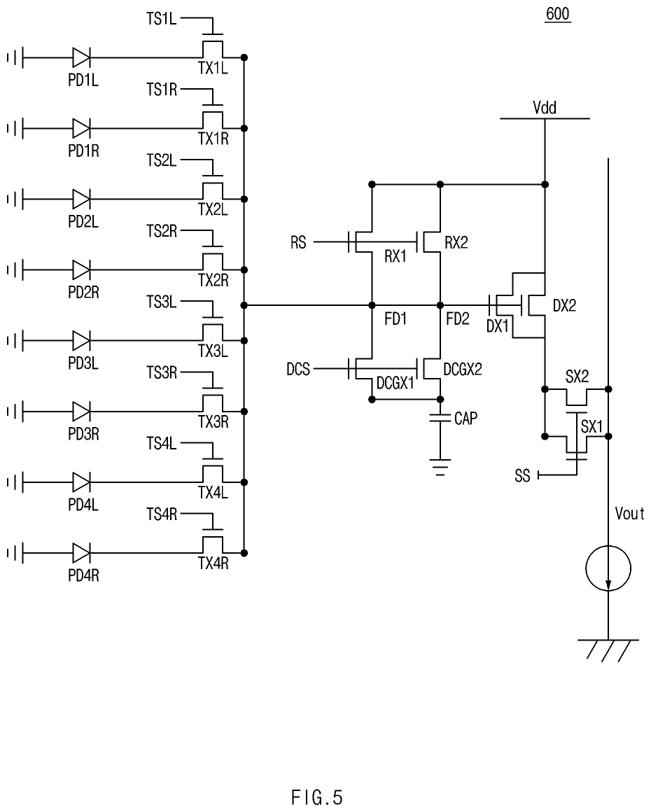

FIG. 5 is an equivalent circuit diagram 600 illustrating an example of the first unit pixel PX1 based on some implementations of the disclosed technology.

The circuit diagram of FIG. 5 shows the connection relationship between elements (e.g., PD1L, TX1L, FD1, etc.) included in the first unit pixel PX1.

Referring to FIG. 5, eight transfer transistors (TX1L-TX4R) are included in the first unit pixel PX1, and photoelectric conversion elements (PD1L-PD4R) respectively correspond to the transfer transistors (TX1L-TX4R).

A transfer control signal (e.g., TS1L) may be applied to a gate of each transfer transistor (e.g., TX1L). According to the voltage level of each transfer control signal (TS1L-TS4R), charges generated by each photoelectric conversion element (PD1L-PD4R) may be transferred to the floating diffusion regions (FD1, FD2) through the transfer transistor (TX1L-TX4R) corresponding to the photoelectric conversion element (PD1L-PD4R). In some implementations, according to the voltage level of the transfer control signal TS1L, charges generated by the photoelectric conversion element PD1L may be transferred to the floating diffusion regions (FD1, FD2) through the transfer transistor TX1L corresponding to the photoelectric conversion element PD1L. Also in this way, according to the voltage level of the transfer control signal TS4R, charges generated by the photoelectric conversion element PD4R may be transferred to the floating diffusion regions (FD1, FD2) through the transfer transistor TX4R corresponding to the photoelectric conversion element PD4R.

The first floating diffusion region FD1 connected to the four photoelectric conversion elements (PD1L-PD2R) may be connected to the second floating diffusion region FD2 connected to the other four photoelectric conversion elements (PD3L-PD4R). In other words, the first floating diffusion region FD1 and the second floating diffusion region FD2 may be shared by eight photoelectric conversion elements (PD1L-PD4R).

The reset transistors (RX1, RX2) may be connected in parallel to each other, and may be controlled by one reset control signal RS. The source/drain of the reset transistors (RX1, RX2) and the floating diffusion regions (FD1, FD2) may be connected to each other. In some implementations, the source/drain of the reset transistor RX1 may be connected to the floating diffusion region FD1, and the source/drain of the reset transistor RX2 may be connected to the floating diffusion region FD2.

The reset transistors (RX1, RX2) may remove charges from the floating diffusion regions (FD1, FD2) and from the photoelectric conversion elements (PD1L-PD4R) connected to the floating diffusion regions (FD1, FD2), and may reset the first unit pixel PX1 to the pixel voltage VDD.

In some implementations, whether to reset the first unit pixel PX1 may be determined depending on the voltage level of the reset control signal RS applied to the reset transistors (RX1, RX2).

The drive transistors (DX1, DX2) may be connected in parallel to each other, and the floating diffusion regions (FD1, FD2) may be connected to the gates of the drive transistors (DX1, DX2).

The floating diffusion regions (FD1, FD2) may be connected to the gates of the drive transistors (DX1, DX2).

The drive transistors (DX1, DX2) may operate as source follower transistors that amplify a voltage change corresponding to charges stored in the floating diffusion regions (FD1, FD2). One end of the drive transistors (DX1, DX2) may be connected to the pixel voltage VDD, and the other end of the drive transistors (DX1, DX2) may be connected to the selection transistors (SX1, SX2).

Gain conversion transistors (DCGX1, DCGX2) may be connected between the floating diffusion regions (FD1, FD2) and the capacitive element CAP. In some implementations, the gain conversion transistors DCGX1 may be connected between the floating diffusion region FD1 and the capacitive element CAP, and the gain conversion transistor DCGX2 may be connected between the floating diffusion region FD2 and the capacitive element CAP.

The gain conversion transistors (DCGX1, DCGX2) may be connected in parallel to each other, and may be controlled by one gain control signal DCS.

One end of the source/drain of the gain conversion transistors (DCGX1, DCGX2) may be connected to the floating diffusion regions (FD1, FD2), and the other end of the source/drain of the gain conversion transistors (DCGX1, DCGX2) may be connected to the capacitive element CAP.

In some implementations, whether the floating diffusion regions FD1 and FD2 are connected to the capacitive element CAP may be determined depending on whether the gain conversion transistors DCGX1 and DCGX2 are activated or deactivated.

For example, when the gain conversion transistors (DCGX1, DCGX2) are activated, the floating diffusion regions (FD1, FD2) and the capacitance element CAP may be connected to each other so that the actual capacity of the floating diffusion regions (FD1, FD2) can increase.

When the actual capacity of the floating diffusion regions (FD1, FD2) increases, the floating diffusion regions (FD1, FD2) may not be saturated even if the amount of photocharge transferred from the photoelectric conversion elements (PD1L-PD4R) increases. Accordingly, operation characteristics may be improved in a high-illuminance environment in which a large amount of photocharge occurs in the photoelectric conversion elements (PD1L-PD4R).

In the low-illuminance environment, the gain conversion transistors (DCGX1, DCGX2) may be deactivated. When the amount of photocharge generated in the photoelectric conversion elements (PD1L-PD4R) is small, the sensitivity of the floating diffusion regions (FD1, FD2) may increase by separating the floating diffusion regions (FD1, FD2) and the capacitor element CAP from each other.

The selection transistors (SX1, SX2) may be connected in parallel to each other to operate as one transistor.

The selection transistors (SX1, SX2) may determine whether to output the pixel signal (Vout) corresponding to the voltage change amplified by the drive transistors (DX1, DX2). Whether or not the selection transistors (SX1, SX2) output the pixel signal (Vout) may be determined depending on a voltage level of a selection control signal SS applied to gate electrodes of the selection transistors (SX1, SX2).

The output pixel signal (Vout) may be processed by a component (e.g., the image sensor 100) included in the image sensing device (e.g., ISD) to generate a signal corresponding to incident light.

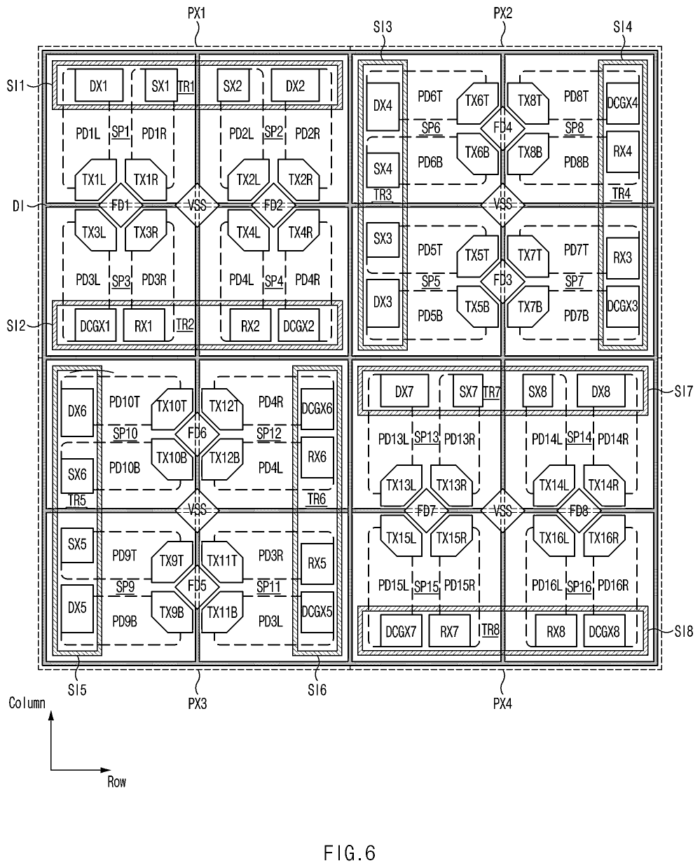

FIG. 6 is a layout diagram illustrating an example of the first to fourth unit pixels PX1 to PX4 based on some implementations of the disclosed technology.

Referring to FIG. 6, each of the unit pixels PX1 to PX4 based on some implementations of the disclosed technology may be formed in a square shape with two perpendicular sides having the same length.

The second unit pixel PX2 and the third unit pixel PX3 that are in contact with the first unit pixel PX1 may have a layout structure obtained by rotating the layout of the first unit pixel PX1 by 90°.

The second unit pixel PX2 may be isolated or separated from other adjacent unit pixels by the isolation structure (DI). The second unit pixel PX2 may have a square shape in which the row-directional length of the pixel array is identical to the column-directional length of the pixel array.

The second unit pixel PX2 may include fifth to eighth sub-pixels SP5 to SP8. Each sub-pixel (e.g., SP5) may include two photoelectric conversion elements (e.g., PD5B, PD5T) and transfer transistors (e.g., TX5B, TX5T) formed to overlap the photoelectric conversion elements (e.g., PD5B, PD5T).

The sub-pixels included in the second unit pixel PX2 may include photoelectric conversion elements (e.g., PD5B, PD5T) arranged in the column direction of the pixel array.

The photoelectric conversion elements (e.g., PD5B, PD5T) and the transfer transistors (e.g., TX5B, TX5T) included in the fifth to eighth sub-pixels SP5 to SP8 may be respectively arranged symmetrical with respect to the column direction of the pixel array.

The image sensing device (ISD) of FIG. 1 may generate phase difference data by comparing pixel signals corresponding to photoelectric conversion elements (PD5B, PD6B, PD7B, PD8B) located at a lower side with respect to the column direction of the pixel array with pixel signals corresponding to photoelectric conversion elements (PD5T, PD6T, PD7T, PD8T) located at an upper side with respect to the column direction of the pixel array.

The second unit pixel PX2 may include a third transistor region TR3 located along a fifth side of the second unit pixel PX2, and a fourth transistor region TR4 located along a sixth side parallel to the fifth side. The fifth side of the second unit pixel PX2 may be in contact with a fourth side of the first unit pixel PX1. The fourth side of the first unit pixel PX1 may be a side facing or opposite to a third side of the first unit pixel PX1 (see FIG. 1).

The third transistor region TR3 may extend in a direction perpendicular to the first transistor region TR1 of the first unit pixel PX1. In some implementations, the first transistor region TR1 may extend in the row direction of the pixel array, and the third transistor region TR3 may extend in the column direction of the pixel array.

For example, the third transistor region TR3 may include drive transistors (DX3, DX4) and selection transistors (SX3, SX4), and the fourth transistor region TR4 may include gain conversion transistors (DCGX3, DCGX4) and reset transistors (RX3, RX4).

Transistors included in the third transistor region TR3 and transistors included in the fourth transistor region TR4 may respectively be arranged in a symmetrical shape.

In some implementations, the layout structure of the unit pixel PX2 may be configured such that the unit pixel PX2 includes additional capacitive elements by arranging dummy transistors instead of the fourth gain conversion transistor DCGX4 and the fourth reset transistor RX4.

The third transistor region TR3 may be disposed across the fifth sub-pixel SP5 and the sixth sub-pixel SP6, and the fourth transistor region TR4 may be disposed across the seventh sub-pixel SP7 and the eighth sub-pixel SP8.

The second unit pixel PX2 may include a third junction region SI3 surrounding the third transistor region TR3 and a fourth junction region SI4 surrounding the fourth transistor region TR4.

The third junction region SI3 and the fourth junction region SI4 may include impurities and may extend from the other surface of the semiconductor substrate including the photoelectric conversion elements (e.g., PD5B, PD5T) toward one surface opposite to the other surface of the semiconductor substrate.

The junction regions (e.g., SI3, SI4) and the isolation structure (DI) may be arranged to be in contact with different sides of the semiconductor substrate.

In some implementations, at least a portion of the junction region (e.g., SI3, SI4) may be arranged to overlap the isolation structure (DI).

As described above, the width of the junction region (e.g., SI3, SI4) may be smaller than the width of the isolation structure (DI) surrounding the unit pixel (e.g., PX2). For example, as shown in FIG. 6, the length of the third junction region SI3 or the length of the fourth junction region SI4 in the column direction of the pixel array may be shorter than the column-directional length of the isolation structure (DI) surrounding the unit pixel (e.g., PX2).

In addition, the second unit pixel PX2 may include a plurality of floating diffusion regions (FD3, FD4) and a ground region VSS that overlap the isolation structure (DI).

The floating diffusion regions (FD3, FD4) and the ground region VSS may be arranged in a direction (e.g., the column direction of the pixel array) in which the fifth side of the second unit pixel PX2 is elongated.

The second unit pixel PX2 may have a square layout having a fifth side, a sixth side, a seventh side, and an eighth side. The fifth side of the second unit pixel PX2 may be parallel to the sixth side of the second unit pixel PX2, and the seventh side of the second unit pixel PX2 may be parallel to the eighth side of the second unit pixel PX2. In addition, the fifth side of the second unit pixel PX2 may be perpendicular to the seventh and eighth sides of the second unit pixel PX2.

The fifth side may be a side extending in the column direction of the pixel array, and the seventh side may be a side extending in the row direction of the pixel array. As described above, the fifth side of the second unit pixel PX2 may be in contact with the fourth side of the first unit pixel PX1.

The third unit pixel PX3 may have the same layout as the second unit pixel PX2. The fourth unit pixel PX4 may have the same layout as the first unit pixel PX1.

The image sensing device ISD may include not only photoelectric conversion elements (e.g., PD1L, PD1R) adjacent to each other in the row direction, but also photoelectric conversion elements (e.g., PD5B, PD5T) adjacent to each other in the column direction, thereby performing a phase-difference detection autofocus (PDAF) function in all directions including up, down, left, and right directions of the pixel array.

When the layout of each unit pixel is not a square layout, it may be difficult for the pixel array to include both the photoelectric conversion elements (e.g., PD1L, PD1R) adjacent to each other in the row direction and the photoelectric conversion elements (e.g., PD5B, PD5T) adjacent to each other in the column direction, and it may also be difficult to sufficiently secure a region where the photoelectric conversion elements will be placed and a region where the transistors will be placed.

In addition, since each unit pixel has a square layout and adjacent unit pixels have the same layout when rotated by 90°, it is possible to reduce noise that may occur due to such layout.

As the noise caused by such layout is reduced, the asymmetry between phase-difference detection in the row direction of the pixel array and phase-difference detection in the column direction of the pixel array can be reduced or minimized.

In other words, the image sensing device can secure symmetry between the pixel signal output from the unit pixel (e.g., PX1) including photoelectric conversion elements (e.g., PD1L, PD1R) adjacent to each other in the row direction and the pixel signal output from the other unit pixel (e.g., PX2) including the photoelectric conversion elements (e.g., PD5B, PD5T) adjacent to each other in the column direction, and thus the amount of noise caused by directional differences of the phase-difference detection autofocus (PDAF) function can be minimized.

As is apparent from the above description, the image sensing device based on some implementations of the disclosed technology can improve operation characteristics when performing a phase-difference detection autofocus (PDAF) function.

The image sensing device based on some implementations of the disclosed technology may be formed to have unit pixels, each of which has a row-directional length and a column-directional length identical to each other, resulting in an increased degree of freedom in arranging such unit pixels.

The image sensing device based on some implementations of the disclosed technology can secure symmetry between a pixel signal output from a unit pixel including photoelectric conversion elements adjacent to each other in the row direction of the pixel array and another pixel signal output from a unit pixel including photoelectric conversion elements adjacent to each other in the column direction of the pixel array.

The embodiments of the disclosed technology may provide a variety of effects capable of being directly or indirectly recognized through the above-mentioned patent document.

Although a number of illustrative embodiments have been described, it should be understood that modifications and/or enhancements to the disclosed embodiments and other embodiments can be devised based on what is described and/or illustrated in this patent document.

What is claimed is:

1. An image sensing device comprising:
a plurality of unit pixels configured to generate electrical signals based on incident light and arranged in a row direction or a column direction of a pixel array,
wherein the plurality of unit pixels includes a first unit pixel, wherein the first unit pixel includes:
a first sub-pixel, a second sub-pixel, a third sub-pixel and a fourth sub-pixel arranged in a 2×2 matrix;
an isolation structure including a first portion and a second portion, the first portion formed to surround the first unit pixel, the second portion disposed between adjacent sub-pixels among the first sub-pixel to the fourth sub-pixel;
a first junction region formed to surround a first transistor region and disposed across the first sub-pixel and the second sub-pixel along a first side of the first unit pixel; and
a second junction region formed to surround a second transistor region and disposed across the third sub-pixel and the fourth sub-pixel along a second side parallel to the first side,
wherein a length of the first side is equal to a length of a third side of the first unit pixel perpendicular to the first side.

2. The image sensing device according to claim 1, wherein each of the first sub-pixel, the second sub-pixel, the third sub-pixel, and the fourth sub-pixel includes:
two photoelectric conversion elements that generate photocharge in response to incident light and disposed adjacent to each other.

3. The image sensing device according to claim 2, wherein:
the two photoelectric conversion elements are arranged adjacent to each other in the row direction or the column direction of the pixel array.

4. The image sensing device according to claim 2, wherein:
each of the first to fourth sub-pixels includes transfer transistors that respectively overlap the two photoelectric conversion elements.

5. The image sensing device according to claim 2, wherein:
each of the photoelectric conversion elements includes a deep-doped region where impurities are doped to a first depth from a surface of the first unit pixel and a shallow-doped region where impurities are doped to a second depth from the surface of the first unit pixel, wherein the second depth is closer to the surface of the first unit pixel than the first depth.

6. The image sensing device according to claim 2, wherein the first unit pixel includes:
a first floating diffusion region disposed between the first sub-pixel and the third sub-pixel; and
a second floating diffusion region disposed between the second sub-pixel and the fourth sub-pixel.

7. The image sensing device according to claim 6, wherein:
the first floating diffusion region and the second floating diffusion region are arranged in a direction in which the first side extends.

8. The image sensing device according to claim 1, wherein:
the first transistor region includes a drive transistor and a selection transistor; and
the second transistor region includes a gain conversion transistor and a reset transistor.

9. The image sensing device according to claim 1, wherein:
each of the first to fourth sub-pixels is formed in a square shape.

10. The image sensing device according to claim 1, wherein the plurality of unit pixels includes a second unit pixel in contact with the first unit pixel, wherein the second unit pixel includes:
a third junction region formed to surround a third transistor region and disposed across a fifth sub-pixel and a sixth sub-pixel along a fifth side of the second unit pixel; and
a fourth junction region formed to surround a fourth transistor region and disposed across a seventh sub-pixel and an eighth sub-pixel along a sixth side parallel to the fifth side,
wherein the fifth side is in contact with a fourth side of the first unit pixel extending in a direction perpendicular to the first side.

11. The image sensing device according to claim 3, wherein the plurality of unit pixels includes a second unit pixel in contact with the first unit pixel, wherein the second unit pixel includes:
a fifth sub-pixel, a sixth sub-pixel, a seventh sub-pixel, and an eighth sub-pixel arranged in a 2×2 matrix,
wherein:
each of the fifth sub-pixel, the sixth sub-pixel, the seventh sub-pixel, and the eighth sub-pixel includes two photoelectric conversion elements; and
the photoelectric conversion elements included in each of the fifth sub-pixel, the sixth sub-pixel, the seventh sub-pixel, and the eighth sub-pixel are arranged to be adjacent to each other in a direction perpendicular to a direction in which photoelectric conversion elements included in each of the first sub-pixel, the second sub-pixel, the third sub-pixel, and the fourth sub-pixel are arranged.

12. The image sensing device according to claim 11, wherein the second unit pixel further includes:
a third floating diffusion region disposed between the fifth sub-pixel and the seventh sub-pixel; and
a fourth floating diffusion region disposed between the sixth sub-pixel and the eighth sub-pixel,
wherein the third floating diffusion region and the fourth floating diffusion region are arranged in a direction in which the photoelectric conversion elements included in each of the fifth sub-pixel, the sixth sub-pixel, the seventh sub-pixel, and the eighth sub-pixel are arranged.

13. The image sensing device according to claim 1, wherein:
the first transistor region includes a plurality of pixel transistors connected in parallel to each other.

14. The image sensing device according to claim 13, wherein:
the pixel transistors include at least one of a drive transistor, a selection transistor, a reset transistor, or a gain conversion transistor.

15. The image sensing device according to claim 1, wherein the first unit pixel further includes:
a ground region disposed at a center of the first unit pixel and configured to receive a ground voltage as an input.

16. The image sensing device according to claim 1, wherein:
the second transistor region includes a capacitive element.

17. The image sensing device according to claim 2, wherein:
the isolation structure is formed in a trench structure extending from one surface of a semiconductor substrate toward another surface opposite to the one surface of the semiconductor substrate, and wherein the semiconductor substrate is which the photoelectric conversion elements are arranged.

18. The image sensing device according to claim 17, wherein:
the first junction region or the second junction region is an impurity region extending from the other surface of the semiconductor substrate toward the one surface of the semiconductor substrate.

19. The image sensing device according to claim 18, wherein:
the first junction region or the second junction region is formed to at least partially overlap the isolation structure.

20. The image sensing device according to claim 18, wherein:
a width of the first junction region or a width of the second junction region is smaller than a width of the isolation structure surrounding the first unit pixel.
